(19) United States
(12) Patent Application Publication
(10) Pub. No.: US 2016/0093581 A1
(43) Pub. Date: Mar. 31, 2016

(54) SEMICONDUCTOR DEVICE WITH A THROUGH ELECTRODE

(71) Applicant: SK hynix Inc., Icheon (KR)

(72) Inventors: Rae Hyung JEONG, Seoul (KR); Hyun Kyu RYU, Seoul (KR)

(21) Appl. No.: 14/957,115

(22) Filed: Dec. 2, 2015

Related U.S. Application Data
(62) Division of application No. 14/290,731, filed on May 29, 2014.

(30) Foreign Application Priority Data
Dec. 23, 2013 (KR) 10-2013-0161190

(51) Int. Cl. H01L 23/00

(52) U.S. Cl. CPC H01L 24/05; H01L 24/03; H01L 24/13; H01L 2224/0391; H01L 2224/02372; H01L 2224/0401; H01L 2224/05008; H01L 2224/13026

(57) ABSTRACT

A semiconductor device includes a through electrode penetrating a substrate such that a first end portion of the through electrode protrudes from a first surface of the substrate, a passivation layer covering the first surface of the substrate and a sidewall of the first end portion of the through electrode, a bump having a lower portion penetrating the passivation layer and coupled to the first end portion of the through electrode, and a lower metal layer disposed between the bump and the first end portion of the through electrode. The lower metal layer extends onto a sidewall of the bump and has a concave shape.

### CROSS-REFERENCE TO RELATED APPLICATION

The present application claims priority under 35 U.S.C. 119(a) to Korean Application No. 10-2013-0161190, filed on Dec. 23, 2013, in the Korean intellectual property Office, which is incorporated herein by reference in its entirety.

### BACKGROUND

1. Technical Field

Embodiments of the present disclosure relate to semiconductor devices, and more particularly, to semiconductor devices having through electrodes and methods of manufacturing the same.

2. Related Art

Semiconductor devices employed in electronic systems may include various electronic circuit elements, and the electronic circuit elements may be integrated in and/or on a semiconductor substrate to constitute the semiconductor device (also referred to as a semiconductor chip or a semiconductor die). Memory semiconductor chip may be packaged and be employed in the electronic systems. These semiconductor packages may be employed in the electronic systems, for example, computers, mobile systems or data storage media.

As mobile systems such as smart phones become lighter and smaller, the semiconductor packages employed in the mobile systems have been continuously scaled down. In addition, large capacitive semiconductor packages are increasingly in demand with the development of multi-functional mobile systems. In connection with these developments, efforts to put a plurality of semiconductor devices in a single package have been made to provide large capacitive semiconductor packages such as stack packages. Further, through silicon via (TSV) electrodes penetrating semiconductor chips have been proposed to realize interconnected structures that electrically connect the semiconductor chips in a single stack package to each other.

In fabrication of the interconnection structures, efforts have been directed to improving the structural and electrical reliability between the TSV electrodes and conductive materials contacting the TSV electrodes. An inter-metallic compound material may be generated by chemical reactions between a copper material of the TSV and a solder material to degrade the reliability of the interconnection structures.

### SUMMARY

Various embodiments are directed to semiconductor devices having through electrodes, methods of manufacturing the same, memory cards including the same and electronic systems including the same.

According to some embodiments, a semiconductor device includes a through electrode penetrating a substrate such that a first end portion of the through electrode protrudes from a first surface of the substrate, a passivation layer covering the first surface of the substrate and a sidewall of the first end portion of the through electrode, a bump having a lower portion penetrating the passivation layer and coupled to the first end portion of the through electrode, and a lower metal layer with a concave shape disposed between the bump and the first end portion of the through electrode and covering a sidewall of the bump.

According to further embodiments, a semiconductor device includes a through electrode penetrating a first substrate such that a first end portion of the through electrode protrudes from a first surface of the first substrate, a passivation layer covering the first surface of the first substrate and a sidewall of the first end portion of the through electrode, a first bump having a lower portion penetrating the passivation layer and coupled to the first end portion of the through electrode, a lower metal layer with a concave shape disposed between the first bump and the first end portion of the through electrode and covering a sidewall of the first bump, a second substrate stacked on the first substrate, and a second bump coupled to the second substrate and combined with the first bump.

According to further embodiments, a method of manufacturing a semiconductor device includes forming a passivation layer on a first surface of a substrate to cover a first end portion of a through electrode penetrating the substrate. The first end portion of the through electrode protrudes from the first surface of the substrate. A template pattern is formed on the passivation layer to expose a portion of the passivation layer vertically overlapping with the first end portion of the through electrode. The exposed portion of the passivation layer is etched to form an opening that exposes the first end portion of the through electrode. A lower metal layer contacting the first end portion of the through electrode is formed. A bump is formed in the opening surrounded by the lower metal layer. The template pattern is removed.

According to further embodiments, a method of manufacturing a semiconductor device includes forming a through electrode penetrating a substrate such that a first end portion of the through electrode protrudes from a first surface of the substrate, forming a passivation layer that covers the first surface of the substrate and a sidewall of the first end portion of the through electrode, forming a lower metal layer over the first end portion of the through electrode, forming a bump having a lower portion that is penetrates the passivation layer and is coupled to the first end portion of the through electrode through the lower metal layer. The lower metal layer extends onto a sidewall of the bump and has a concave shape.

According to further embodiments, a memory card includes a memory and a memory controller suitable for controlling an operation of the memory. The memory includes a through electrode penetrating a substrate such that a first end portion of the through electrode protrudes from a first surface of the substrate, a passivation layer covering the first surface of the substrate and a sidewall of the first end portion of the through electrode, a bump having a lower portion inserted into the passivation layer to contact the first end portion of the through electrode, and a lower metal layer disposed between the bump and the first end portion of the through electrode. The lower metal layer is formed to extend onto a sidewall of the bump and to have a concave shape.

According to further embodiments, a memory card includes a memory and a memory controller suitable for controlling an operation of the memory. The memory includes a through electrode penetrating a first substrate such that a first end portion of the through electrode protrudes from a first surface of the first substrate, a passivation layer covering the first surface of the first substrate and a sidewall of the first end portion of the through electrode, a first bump having a lower portion inserted into the passivation layer to contact the first end portion of the through electrode, a lower metal layer disposed between the first bump and the first end portion of the through electrode and surrounding a sidewall of the first bump to have a concave shape, a second substrate stacked on the first substrate, and a second bump connected to the second substrate and combined with the first bump.

According to further embodiments, an electronic system includes a memory and a controller coupled with the memory through a bus. The memory or the controller includes a through electrode penetrating a substrate such that a first end portion of the through electrode protrudes from a first surface of the substrate, a passivation layer covering the first surface of the substrate and a sidewall of the first end portion of the through electrode, a bump having a lower portion inserted into the passivation layer to contact the first end portion of the through electrode, and a lower metal layer disposed between the bump and the first end portion of the through electrode. The lower metal layer is formed to extend onto a sidewall of the bump and to have a concave shape.

According to further embodiments, an electronic system includes a memory and a controller coupled with the memory through a bus. The memory or the controller includes a through electrode penetrating a first substrate such that a first end portion of the through electrode protrudes from a first surface of the first substrate, a passivation layer covering the first surface of the first substrate and a sidewall of the first end portion of the through electrode, a first bump having a lower portion inserted into the passivation layer to contact the first end portion of the through electrode, a lower metal layer disposed between the first bump and the first end portion of the through electrode and surrounding a sidewall of the first bump to have a concave shape, a second substrate stacked on the first substrate, and a second bump connected to the second substrate and combined with the first bump.

### BRIEF DESCRIPTION OF THE DRAWINGS

Embodiments of the inventive concept will become more apparent in view of the attached drawings and accompanying detailed description, in which:

FIGS. 1, 2 and 3 are cross-sectional views illustrating a semiconductor device according to an embodiment;

FIGS. 4 and 5 are cross-sectional views illustrating a semiconductor device according to another embodiment;

FIGS. 6 to 13 are cross-sectional views illustrating methods of manufacturing a semiconductor device according to some embodiments;

FIG. 14 is a block diagram illustrating an electronic system employing a memory card including a semiconductor device in accordance with an embodiment; and

FIG. 15 is a block diagram illustrating an electronic system including a semiconductor device in accordance with an embodiment.

### DETAILED DESCRIPTION OF THE EMBODIMENTS

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concept.

It will also be understood that when an element is referred to as being “on,” “above,” “below,” or “under” another element, it can be directly “on,” “above,” “below,” or “under” the other element, respectively, or intervening elements may also be present. Accordingly, the terms such as “on,” “above,” “below,” or “under” which are used herein are for the purpose of describing particular embodiments only and are not intended to limit the inventive concept.

It will be further understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion. Semiconductor chips may be obtained by separating a semiconductor substrate such as a wafer into a plurality of pieces using a die sawing process.

The semiconductor chips may correspond to memory chips or logic chips. The memory chips may include dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits or phase change random access memory (PcRAM) circuits which are integrated on and/or in the semiconductor substrate. The logic chip may include logic circuits which are integrated on and/or in the semiconductor substrate. In some cases, the term “semiconductor substrate” used herein may be construed as a semiconductor chip or a semiconductor die in which integrated circuits are formed.

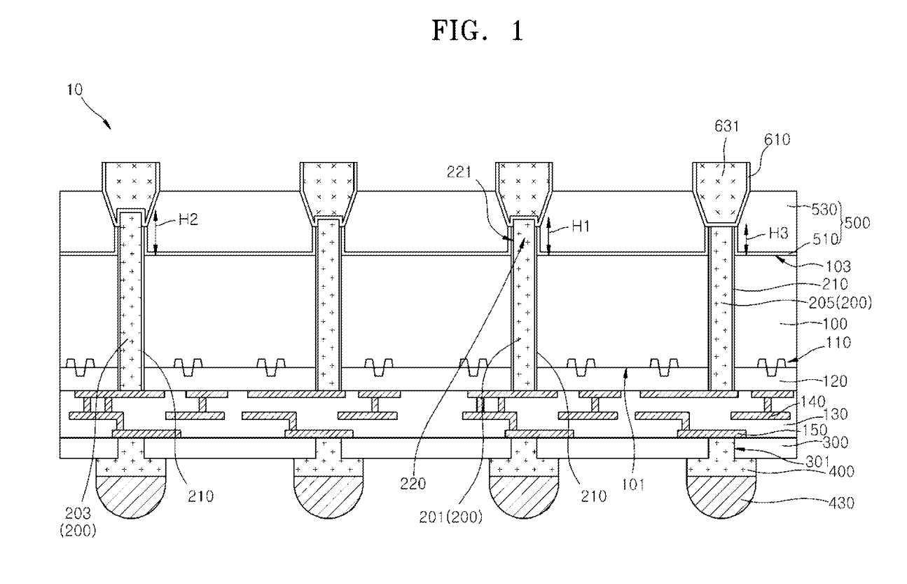

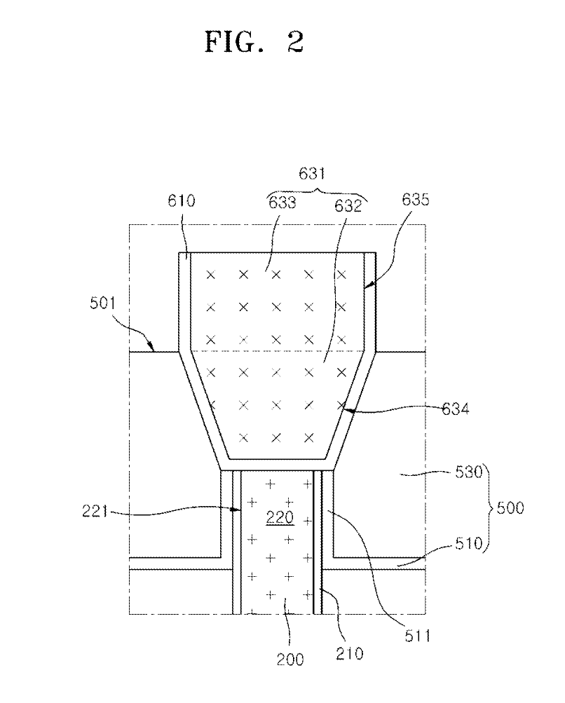

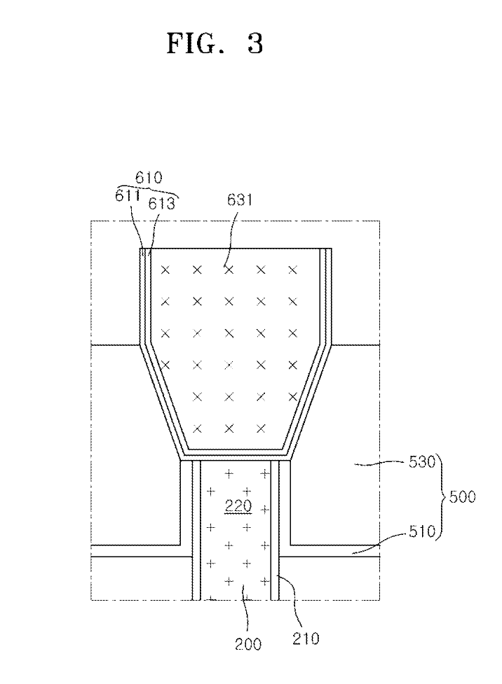

FIG. 1 is a cross-sectional view illustrating a semiconductor device according to an embodiment. FIGS. 2 and 3 are enlarged views illustrating a first conductive bump 631 of the semiconductor device shown in FIG. 1. Referring to FIGS. 1 and 2, the semiconductor device 10 may include a semiconductor substrate 100 and through electrodes 200 that substantially penetrate the semiconductor substrate 100. A first end portion 220 of the through electrode 200 protrudes from a first surface 103 of the semiconductor substrate 100. A first passivation layer 500 may be disposed on the first surface 103 of the semiconductor substrate 100 to cover the first end portions 220 of the through electrodes 200.

Lower portions 632 of first conductive bumps 631 may penetrate the first passivation layer 500 to contact the first end portions 220 of the through electrodes 200. As a result, sidewalls of the first end portions 220 of the through electrodes 200 and sidewalls of the lower portions 632 of the first conductive bumps 631 may be surrounded by the first passivation layer 500. A lower metal layer 610 may be disposed between the first end portion 220 of each through electrode 200 and the lower portion 632 of each first conductive bump 631. In addition, the lower metal layer 610 may extend to surround a sidewall 634 of the lower portion 632 of the first conductive bump 631. Thus, the lower metal layer 610 may have a concave shape.

The semiconductor substrate 100 may be configured to include the through electrodes 200, and the through electrodes 200 may correspond to through silicon via (TSV) electrodes if the semiconductor substrate 100 is a silicon substrate. The through electrodes 200 may correspond to conductive vias that extend from a second surface 101 (e.g. a front side surface) of the semiconductor substrate 100 toward the first surface 103 (e.g. a backside surface) of the semiconductor substrate 100. The semiconductor substrate 100 may be a silicon substrate, and may be an individual chip or a wafer.

Referring to FIG. 1, a second surface 101 of the semiconductor substrate 100 may be an active layer with integrated circuits. A first surface 103 may be opposite to the second surface 101. Circuit elements of an integrated circuit, such as transistors 110, may be disposed on the second surface 101. A first dielectric layer 120 covers the circuit elements and a second interlayer dielectric layer 130 is formed on the first dielectric layer 120. An internal interconnection structure 140 may be formed in the second dielectric layer 130 as multi-layered interconnections. The transistors 110 may act as cell transistors constituting memory cells of a memory device or may constitute logic circuits of a logic device.

The internal interconnection structure 140 may include interconnection lines and connection vias. Second conductive bumps 400 acting as external connection terminals may be disposed on contact pads 150 which are electrically connected to the internal interconnection structure 140. The second conductive bumps 400 may be electrically connected to the through electrodes 200 to act as front bumps. The second conductive bumps 400 may be opposite to the first conductive bumps 631 disposed on the first surface 103 of the semiconductor substrate 100. A second passivation layer 300 including insulant material and acting as a front side passivation layer may be disposed on the interlayer dielectric layer 130 to expose the second conductive bumps 400. The second conductive bumps 400 may be connected to contact pads 150 through openings 301 of the second passivation layer 300.

The through electrodes 200 may be electrically connected to the second conductive bumps 400 through the internal interconnection structure 140, as illustrated in FIG. 1. However, in some embodiments, the through electrodes 200 may be directly connected to the second conductive bumps 400 or each of the through electrodes 200 and the corresponding second conductive bump 400 may constitute a single unified body without any heterogeneous junction therebetween. The second conductive bumps 400 may include a metal material such as a copper material or an alloy material containing copper.

Conductive adhesion portions 430 may be disposed on the second conductive bumps 400 to improve the contact reliability between the second conductive bumps 400 and other connection terminals. The conductive adhesion portions 430 may include a solder material. The solder material may include tin (Sn). An interfacial layer (not shown) may be additionally disposed between the conductive adhesion portions 430 and the second conductive bumps 400. The interfacial layer may act as a wetting layer or a barrier layer suppressing contamination or oxidation of the second conductive bumps 400. The interfacial layer may contain a nickel material, a gold material, or a combination thereof.

The through electrodes 200 may be fabricated using a process technology for forming TSV electrodes. Each of the through electrodes 200 may include a metal material such as a copper material or a copper alloy material containing silicon. In some embodiments, each of the through electrodes 200 may include gallium (Ga), indium (In), tin (Sn), silver (Ag), bismuth (Bi), lead (Pb), gold (Au), zinc (Zn), aluminum (Al), or an alloy containing at least one of these elements. Each of the through electrodes 200 may penetrate the semiconductor substrate 100 and have a through via shape, and the first end portion 220 (corresponding to backside end portions of the through electrodes 200) may protrude from the first surface 103 of the semiconductor substrate 100 opposite to the second surface 101. An electrode insulation layer 210 may surround sidewalls of the through electrodes 200 to electrically insulate the through electrodes 200 from the semiconductor substrate 100. The electrode insulation layer 210 may prevent copper ions in the through electrodes 200 from diffusing or migrating into the semiconductor substrate 100.

Referring again to FIG. 1, the first end portions 220 of the through electrodes 200 may protrude from the first surface 103 of the semiconductor substrate 100 to be inserted into the first passivation layer 500 covering the first surface 103 of the semiconductor substrate 100. Heights of protrusions of the first end portions 220 may be different from each other according to positions on the substrate 100. A height H2 of the first end portion 220 of the second through electrode 203 may be greater than a height H1 of the first end portion 220 of the first through electrode 201, and a height H3 of the first end portion 220 of the third through electrode 205 may be less than the height H1 of the first end portion 220 of the first through electrode 201. The variance in heights may be due to non-uniformities of fabrication processes for forming the through electrodes 200.

Referring again to FIGS. 1 and 2, the first passivation layer 500 may cover the first surface 103 of the semiconductor substrate 100. The first passivation layer 500 may have a thickness which is greater than any of the heights of the first end portions 220 of the through electrodes 200. The first passivation layer 500 may include an organic material or a polymer material. The first passivation layer 500 may include a polyimide layer. Alternatively, the first passivation layer 500 may include an inorganic material such as silicon oxide (SiO₂), silicon nitride (Si₃N₄) or silicon oxynitride (SiON).

The first passivation layer 500 may have a multi-layered structure including a plurality of dielectric layers that have different dielectric constants. The first passivation layer 500 may include a first dielectric layer 530 and a second dielectric layer 510. The second dielectric layer 510 may cover the first surface 103 of the semiconductor substrate 100 and may vertically extend onto sidewalls 221 of the first end portions 220 to form protection ring portions 511. The protection ring portions 511 may surround sidewalls 221 of the first end portions 220, which may have circular, square, rectangular, or other geometric profiles. The second dielectric layer 510 may be a conformal liner layer.

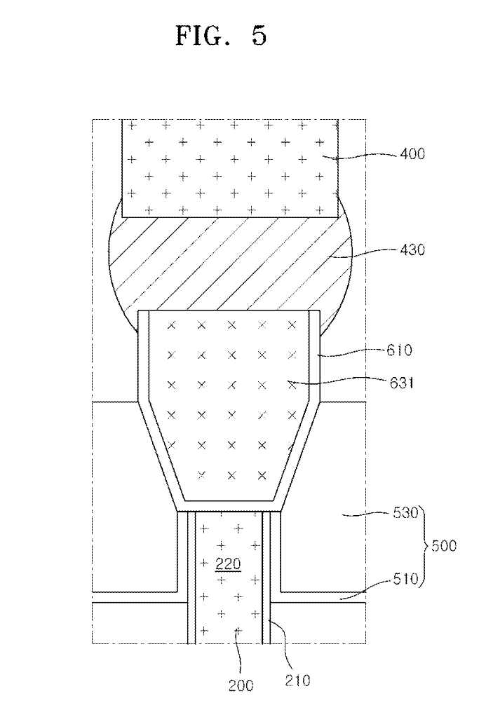

The first dielectric layer 530 may be disposed on the second dielectric layer 510. The first dielectric layer 530 may be deposited on the second dielectric layer 510 and may fill a space surrounded by portions of the second dielectric layer 510 on sidewalls of the end portions 220. In addition, first dielectric layer 530 may act as an insulation buffer layer and as a planarization layer that provides a surface flatness of the first passivation layer 500. That is, the first dielectric layer 530 may provide a substantially flat top surface 501 of the first passivation layer 500. The first dielectric layer may be a stress buffering layer when a stress applied to the first passivation layer 500. Accordingly, when a stress is applied to the first passivation layer 500 during formation of a bump connection structure (see FIG. 5), the first dielectric layer 530 may prevent the mechanical characteristics of the bump connection structure from being degraded. The first dielectric layer 530 may include a silicon oxide (SiO₂) layer.

The second dielectric layer 510 may act as a diffusion barrier layer that blocks the lateral diffusion or lateral migration of the copper ions contained in the first end portions 220 of the through electrodes 200. The second dielectric layer 510 may include silicon nitride (Si₃N₄) or silicon oxynitride (SiON) to effectively block the diffusion or migration of metal ions. If the copper ions contained in the through electrodes 200 are diffused onto the first surface 103 of the semiconductor substrate 100, the copper ions may chemically react with silicon atoms in the semiconductor substrate 100 to generate a copper-silicon compound. In addition, if the copper ions contained in the through electrodes 200 are diffused into the semiconductor substrate 100, the copper ions may degrade characteristics of circuit elements (e.g., transistors) constituting integrated circuits formed in the semiconductor substrate 100.

For example, the copper ions may degrade a threshold voltage characteristic or a leakage current characteristic of the transistors to cause a poor refresh characteristic or a poor standby current characteristic of a memory device. However, according to the present embodiment, the second dielectric layer 510 may effectively prevent the copper ions contained in the through electrodes 200 from being diffused into the semiconductor substrate 100. Accordingly, the second dielectric layer 510 may suppress copper contamination of the semiconductor substrate 100. The first passivation layer 500 may further include an additional diffusion barrier layer or an additional stress buffer layer disposed on the first and second dielectric layers 530 and 510. In such a case, the additional diffusion barrier layer may include silicon nitride (Si₃N₄) or silicon oxynitride (SiON), and the additional stress buffer layer may include silicon oxide (SiO₂).

The first dielectric layer 530 may have a thickness which is greater than any of the heights of the first end portions 220 of the through electrodes 200, and the second dielectric layer 510 may have a thickness which is less than the heights of the first end portions 220 of the through electrodes 200. The first dielectric layer 530 may surround the sidewalls 634 of the lower portions 632 of the first bumps 631, and the second dielectric layer 510 may be disposed between the first dielectric layer 530 and the first surface 103 of the semiconductor substrate 100 as well as between the first dielectric layer 530 and the sidewalls 221 of the first end portions 220 of the through electrodes 200.

Referring again to FIGS. 1 and 2, the lower portions 632 of the first bumps 631 may be embedded in the first passivation layer 500 to contact the first end portions 220 of the through electrodes 200. As described above, the lower metal layer 610 may be disposed between the first conductive bump 631 and the first end portion 220 and may extend to cover the sidewall 634 of the lower portion 632 of the first conductive bump 631. In addition, the lower metal layer 610 may extend to a cover sidewall 635 of an upper portion 633 of the first conductive bump 631, as illustrated in FIG. 2.

Thus, the lower metal layer 610 may have a concave shape surrounding a bottom surface and a sidewall of each of the first conductive bumps 631.

The lower portion 632 of each of the first conductive bumps 631 may correspond to a portion which is embedded in the first passivation layer 500, and the upper portion 633 of each of the first conductive bumps 631 may correspond to a portion that protrudes from the top surface 501 of the first passivation layer 500. Thus, the sidewalls 635 of the upper portions 633 of the first conductive bumps 631 may extend above the top surface 501 of the first passivation layer 500. The lower metal layers 610 may extend onto the sidewalls 635 of the upper portions 633 of the first conductive bumps 631 to protect the upper portions 633 of the first conductive bumps 631.

Referring again to FIG. 2, the lower metal layer 610 may include an under bump metal (UBM) layer disposed under the first conductive bump 631. The lower metal layer 610 may include or act as a seed layer when the first conductive bump 631 is formed using a plating process. When the first conductive bump 631 is formed of a layer of copper using a plating process, the lower metal layer 610 acts as a seed layer which may be a titanium (Ti) layer, a titanium alloy layer, or a combination layer of a titanium (Ti) layer and a copper (Cu) layer. Alternatively, when the first conductive bump 631 is formed of a layer of nickel using a plating process, the lower metal layer 610 acts as a seed layer which may be a titanium (Ti) layer or a combination layer of a titanium (Ti) layer and a copper (Cu) layer.

Referring to FIG. 3, the lower metal layer 610 may include a seed layer 611 in a plating process. The lower metal layer 610 may further include a diffusion barrier layer 613 between the seed layer 611 and the first conductive bump 631. The diffusion barrier layer 613 may be introduced to block the diffusion of metal ions such as copper ions between the first conductive bump 631 and the first end portion 220. The diffusion barrier layer 613 may include a nickel (Ni) layer having a thickness of about 500 angstroms to about 2000 angstroms. In some embodiments, the diffusion barrier layer 613 may further include an oxidation resistant layer such as a gold (Au) layer on the nickel (Ni) layer. Alternatively, the diffusion barrier layer 613 may include a palladium (Pd) layer, a cobalt (Co) layer, a chrome (Cr) layer, a rhodium (Rd) layer, or an alloy layer containing at least two of these materials. The first conductive bump 631 may include nickel (Ni), copper (Cu), or a combination of nickel (Ni) and copper (Cu). For example, the first conductive bump 631 may include a nickel (Ni) pattern having a thickness of about 3000 angstroms to about 20000 angstroms, a copper (Cu) pattern having a thickness of about 1000 angstroms to about 3000 angstroms, or a combination thereof.

In an embodiment in which the diffusion barrier layer 613 includes nickel (Ni), the first conductive bump 631 may include tin (Sn). When the seed layer 611 includes a titanium (Ti) layer, it may be difficult for the seed layer 611 to prevent copper ions in the first end portion 220 of the through electrode 200 from diffusing into the first conductive bump 631 including tin (Sn). Thus, the diffusion barrier layer 613 including a nickel (Ni) layer may be additionally introduced to effectively prevent or suppress the diffusion of copper ions between the first conductive bump 631 and the first end portion 220.

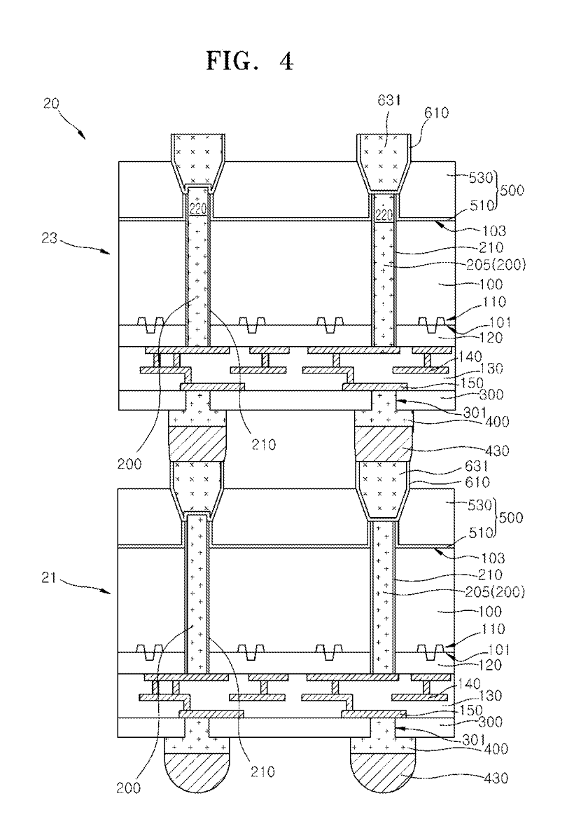

FIG. 4 is across-sectional view illustrating a semiconductor device 20 according to an embodiment, and FIG. 5 is an enlarged view illustrating a bump connection structure of the semiconductor device 20 shown in FIG. 4. Referring to FIGS. 4 and 5, the semiconductor device 20 may include a first semiconductor device 21 and a second semiconductor device 23 stacked on the first semiconductor device 21. Each of the first and second semiconductor devices 21 and 23 may have substantially the same configuration as the semiconductor device 10 described with reference to FIGS. 1, 2 and 3. That is, each of the first and second semiconductor devices 21 and 23 may include a first passivation layer 500 surrounding sidewalls of the first end portions 220 of the through electrodes 200 penetrating the substrate 100 a the lower metal layer 610 surrounding a bottom surface and a sidewall of each of the first bumps 631.

The first conductive bumps 631 of the first semiconductor device 21 may be combined with the second conductive bumps 400 of the second semiconductor device 23 using the conductive adhesion portions 430. The conductive adhesion portions 430 may combine the first conductive bumps 631 of the first semiconductor device 21 with the second conductive bumps 400 of the second semiconductor device 23 to provide a mechanical and electrical bump connection structure of the semiconductor device 20.

Although not shown in the drawings, the semiconductor device 20 may include three or more stacked semiconductor devices. In addition, although not shown in the drawings, the semiconductor device 20 may be mounted on a package substrate such as a printed circuit board (PCB) or an interposer. Alternatively, the semiconductor device 20 may be embedded in an embedded substrate. The semiconductor device 20 may be covered with a protection layer (not shown) such as an epoxy molding compound (EMC).

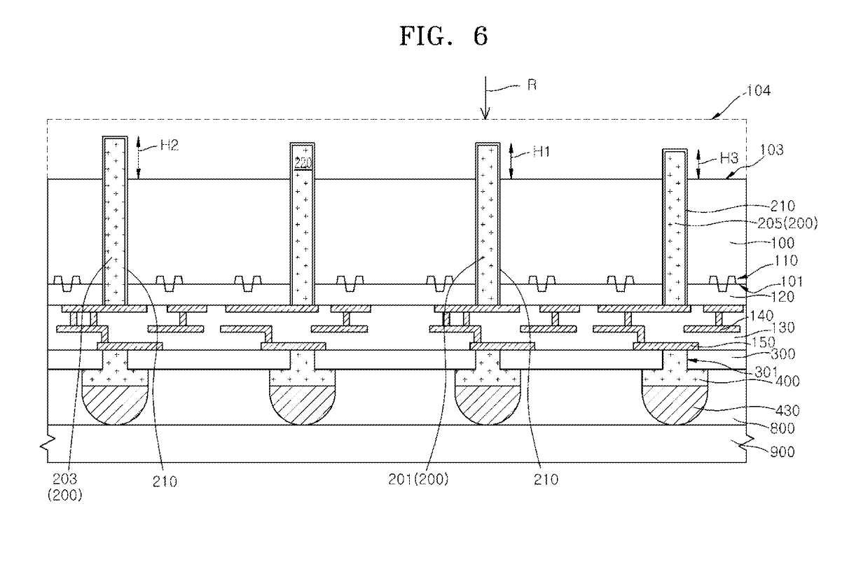

FIGS. 6 to 13 are cross-sectional views illustrating methods of manufacturing a semiconductor device according to some embodiments. Referring to FIG. 6, through electrodes 200 penetrating a semiconductor substrate 100 may be formed. The through electrodes 200 may be formed to extend from a second surface 101 (i.e., a front side surface) of the semiconductor substrate 100 toward a third surface 104 (i.e., an initial backside surface) of the semiconductor substrate 100. The through electrodes 200 may be formed using a process for forming through silicon via (TSV) electrodes at a wafer level. An electrode insulation layer 210 may be formed between the through electrodes 200 and the semiconductor substrate 100 to electrically insulate the through electrodes 200 from the semiconductor substrate 100. The electrode insulation layer 210 may include a silicon oxide material or a silicon nitride material.

Before the through electrodes 200 are formed, circuit elements such as transistors 110 constituting an integrated circuit may be formed on the second surface 101 (corresponding to a surface of an active layer) of the semiconductor substrate 100. The through electrodes 200 may be formed by depositing a conductive material such as a copper (Cu) material. Before forming the through electrodes 200, the electrode insulation layer 210 may be formed.

After forming the through electrodes 200, an interlayer dielectric layer 130 and a multi-layered internal interconnection structure 140 may be formed on the second surface 101 of the semiconductor substrate 100. The internal interconnection structure 140 may include interconnection lines and via plugs electrically connecting the interconnection lines to each other. Contact pads 150 may be formed on a bottom surface of the interlayer dielectric layer 130 opposite to the semiconductor substrate 100. A second passivation layer 300 may be formed on the bottom surface of the interlayer dielectric layer 130 to have openings 301 that expose the contact pads 150 electrically connected to the internal interconnection structure 140.

Second conductive bumps 400 may be formed on the exposed contact pads 150 to provide external connection terminals.

The second conductive bumps 400 may act as front bumps electrically connected to the through electrodes 200. Conductive adhesion portions 430 may be additionally formed on the second conductive bumps 400. Each of the conductive adhesion portions 430 may include a solder layer. The solder layer may be formed of a tin type solder material containing a tin (Sn) material.

The substrate including the second conductive bumps 400 may be attached to an auxiliary substrate 900 such as a carrier substrate using an adhesive agent 800. The auxiliary substrate 900 may be attached to the conductive adhesion portions 430 such that the third surface 104 of the semiconductor substrate 100 is exposed. A recess process R may be applied to the third surface 104 of the semiconductor substrate 100 to form a first surface 103 exposing first end portions 220 of the through electrodes 200.

In more detail, the semiconductor substrate 100 including the conductive adhesion portions 430 may be attached to the auxiliary substrate 900 using the adhesive agent 800, and a predetermined thickness of a backside portion of the semiconductor substrate 100 may be removed by. The backside portion of the semiconductor substrate 100 may be removed using at least one of a dry etch process, a wet etch process and a back grinding process. As a result of the recess process R, the first end portions 220 of the through electrodes 200 may protrude from the first surface 103 of the semiconductor substrate 100.

Heights of the first end portions 220 protruding from the first surface 103 of the semiconductor substrate 100 may be different from each other according to positions on the semiconductor substrate 100. That is, when the through electrodes 200 are formed in the semiconductor substrate 100, depths of the through electrodes 200 may be different from each other according to the positions on the semiconductor substrate 100 because of a non-uniformity of an etch process used in formation of through holes in which the through electrodes 200 are located. Thus, the first end portion 220 of the second through electrode 203 may have a height H2 which is greater than a height H1 of the first end portion 220 of the first through electrode 201, and the first end portion 220 of the third through electrode 205 may have a height H3 which is less than the height H1 of the first end portion 220 of the first through electrode 201.

If the first end portions 220 of the through electrodes 200 have different protrusion heights, a stress may be applied to the first end portion 220 of the second through electrode 203 when a passivation layer covering the through electrodes 200 is planarized to expose the first end portion 220 of at least the third through electrode 205 in a subsequent process. In other words, when the first portions 220 have uneven heights, a process of exposing surfaces of the first portions 220 will expose the taller first portions while the shorter first portions are still buried. The taller, exposed first portions 220 may experience mechanical stresses such as lateral stress from the removal process. If an excessive stress is applied to the first end portion 220 of the second through electrode 203, the second through electrode 203 may be broken or damaged, which may degrade a connection between the second through electrode 203 and a first conductive bump connected to the second through electrode 203 in a subsequent process. However, embodiments of the present disclosure may suppress or prevent the damage of the tallest through electrode 200 such as the second through electrode 203 during a planarization process.

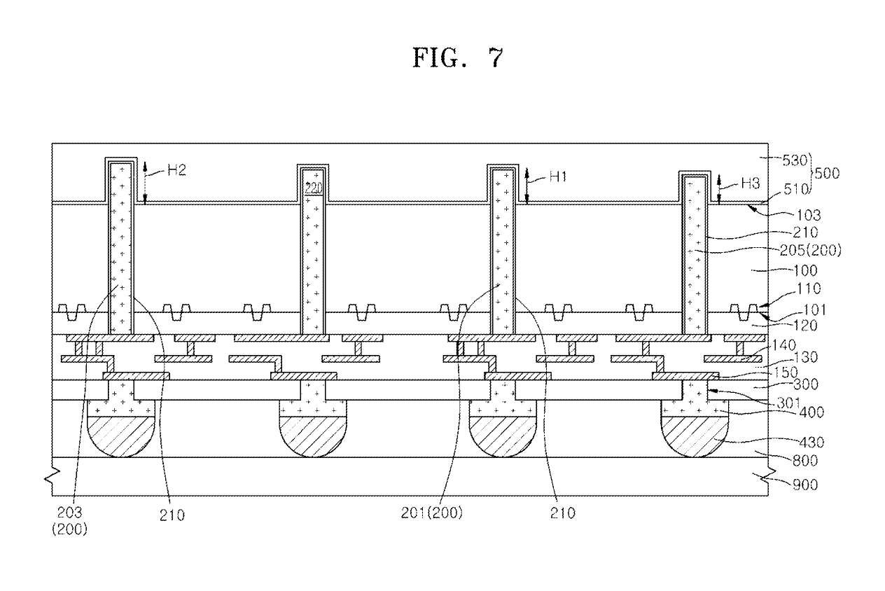

Referring to FIG. 7, a first passivation layer 500 may be formed on the first surface 103 of the semiconductor substrate 100 to cover the first end portions 220 of the through electrodes 200. The first passivation layer 500 may be formed by sequentially stacking a second dielectric layer 510 and a first dielectric layer 530.

The first passivation layer 500 may include an organic material layer or an inorganic material layer. The second dielectric layer 510 may be a silicon nitride layer or a silicon oxynitride layer, and the first dielectric layer 530 may be formed by depositing a silicon oxide layer on the second dielectric layer 510. The first dielectric layer 530 may be thicker than the second dielectric layer 510 such that the first passivation layer 500 covers the second dielectric layer 510 and the first end portions 220, and may provide a substantially even top surface thereof. In some embodiments, when the first passivation layer 500 has an uneven surface, the first dielectric layer 530 may be planarized without exposing the first end portions 220 of the through electrodes 200. In another embodiment, the planarization process applied to the first dielectric layer 530 may be omitted.

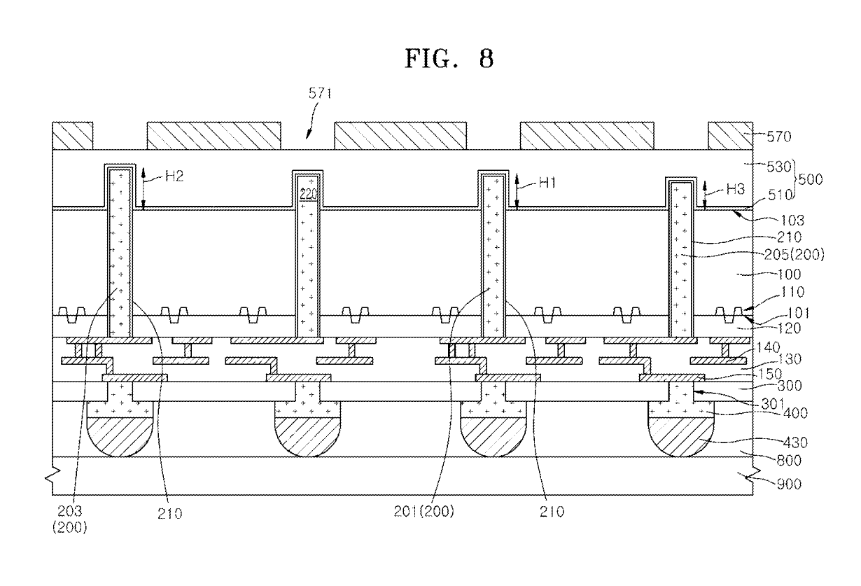

Referring to FIG. 8, a template pattern 570 may be formed on the first passivation layer 500. The template pattern 570 may be formed to have first openings 571 that are aligned with, or vertically overlap with the first end portions 220 of the through electrodes 200. Each of the first openings 571 may have a width which is greater than a width of each first end portion 220. The template pattern 570 may be formed of a dielectric layer having an etch selectivity with respect to the first passivation layer 500 thereunder. For example, the template pattern 570 may be formed by coating a photoresist layer on the first passivation layer 500 and by patterning the photoresist layer using an exposure step and a development step. Alternatively, the template pattern 570 may be formed by depositing a dielectric layer on the first passivation layer 500 and by patterning the dielectric layer using a photolithography process and an etch process.

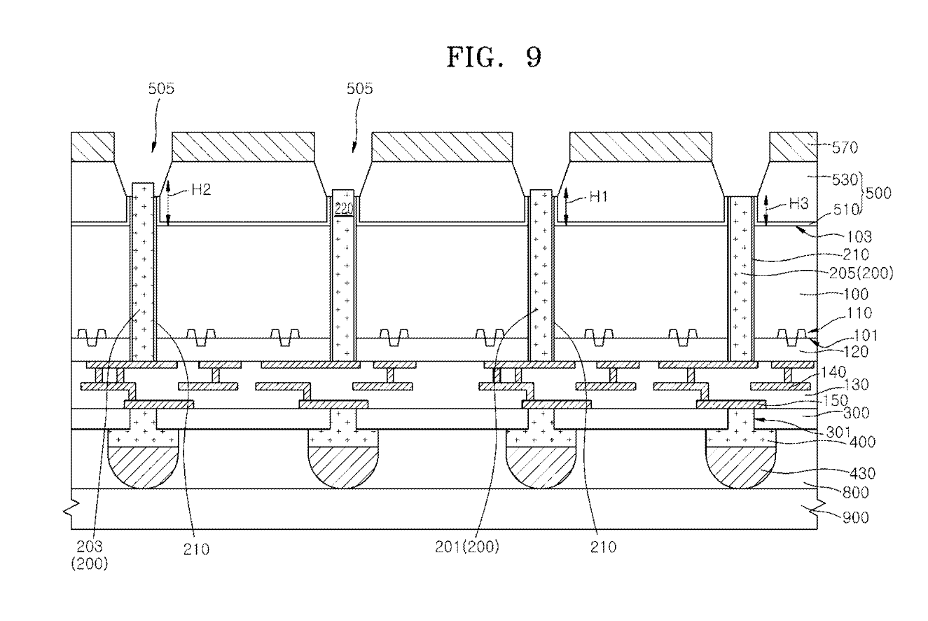

Referring to FIG. 9, the first passivation layer 500 may be etched using the template pattern 570 as an etch mask to form second openings 505 that expose at least top surfaces of the first end portions 220. That is, the second openings 505 may be formed by selectively etching portions of the first passivation layer 500 which are exposed by the first openings 571 of the template pattern 570. In embodiments in which the second dielectric layer 510 is formed of a silicon nitride layer or a silicon oxynitride layer having an etch selectivity with respect to the first dielectric layer 530, portions of the first dielectric layer 530 exposed by the first openings 571 may be etched to expose portions of the second dielectric layer 510, and the exposed portions of the second dielectric layer 510 may be removed to form the second openings 505. In such an embodiment, the second dielectric layer 510 may act as an etch stop layer while the first dielectric layer 530 is etched using the template pattern 570 as an etch mask.

When the second openings 505 are formed by a selective etch process, all of the first end portions 220 may be exposed by the second openings 505 without applying any significant mechanical stresses on the first end portions 220 even when the heights H1, H2 and H3 of the first end portions 220 are different from each other. Thus, all of the first end portions 220 may be exposed without the disadvantages associated with using a process of planarizing the first passivation layer 500 to expose the first end portions 220.

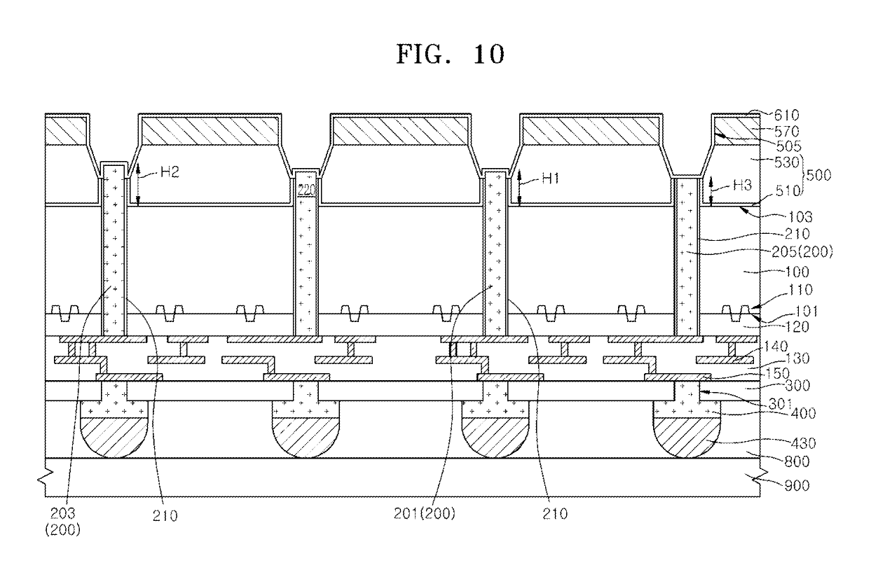

Referring to FIG. 10, a lower metal layer 610 may be formed on the template pattern 570 and in the second openings 505. The lower metal layer 610 may cover exposed surfaces of the first end portions 220 of the through electrodes 200 exposed by the second openings 505. The lower metal layer 610 may be formed of titanium (Ti), copper (Cu), nickel (Ni) or gold (Au). Alternatively, the lower metal layer 610 may include a combination of materials including at least two of titanium (Ti), copper (Cu), nickel (Ni) and gold (Au). The lower metal layer 610 may be formed using a sputtering process. The lower metal layer 610 may cover sidewalls of the second openings 505 and a top surface of the template pattern 570.

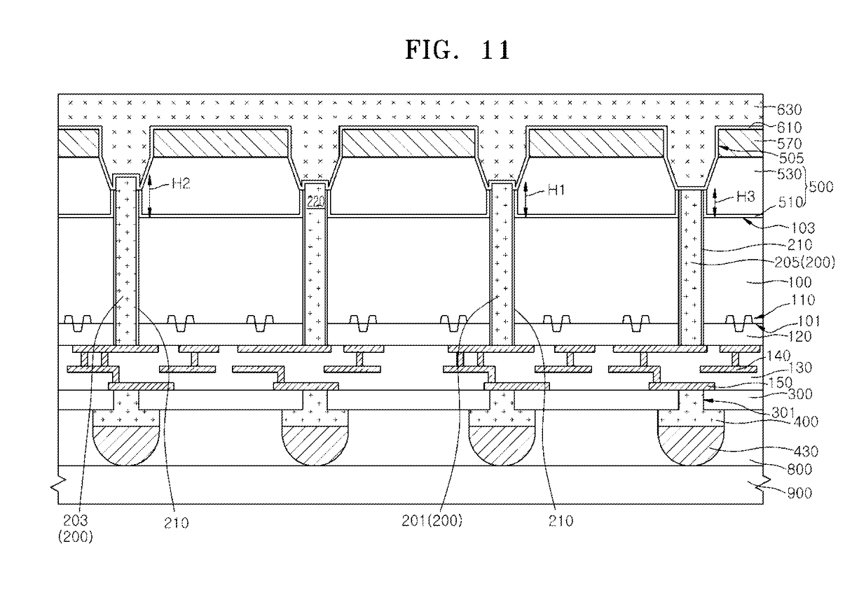

Referring to FIG. 11, a conductive layer 630 may be formed on the lower metal layer 610 to fill the second openings 505. The conductive layer 630 may be formed using a plating process, and the lower metal layer 610 may act as a seed layer during the plating process. When the conductive layer 630 is formed of a single layer of copper using a plating process, the lower metal layer 610 acting as a seed layer may be a titanium (Ti) layer, a titanium alloy layer, or a combination of a titanium (Ti) layer and a copper (Cu) layer. Alternatively, in an embodiment in which the conductive layer 630 is formed of a single layer of nickel using a plating process, the lower metal layer 610 acting as a seed layer may be a titanium (Ti) layer or a combination of a titanium (Ti) layer and a copper (Cu) layer.

In some embodiments, the lower metal layer 610 may serve as a diffusion barrier layer in addition to a seed layer. The diffusion barrier properties may be introduced to prevent metal ions such as copper ions in the first end portions 220 of the through electrodes 200 from diffusing into the conductive layer 630. The diffusion barrier layer may be formed to include a nickel (Ni) layer having a thickness of about 500 angstroms to about 2000 angstroms. An oxidation resistant layer such as a gold (Au) layer may be additionally formed on the diffusion barrier layer.

In some embodiments, the diffusion barrier layer may include palladium (Pd), cobalt (Co), chrome (Cr), rhodium (Rd), or an alloy layer containing at least two of these materials. The conductive layer 630 may include a nickel (Ni) layer, a copper (Cu) layer, or a combination layer of a nickel (Ni) layer and a copper (Cu) layer. For example, the conductive layer 630 may be formed to include a nickel (Ni) layer having a thickness of about 3000 angstroms to about 20000 angstroms, a copper (Cu) layer having a thickness of about 1000 angstroms to about 3000 angstroms, or a combination thereof.

In an embodiment in which the lower metal layer 610 includes a nickel (Ni) layer, the conductive layer 630 may include a tin (Sn) layer. When the seed layer includes a titanium (Ti) layer, it may be difficult for the seed layer to prevent copper ions in the first end portions 220 of the through electrodes 200 from diffusing out. Thus, a diffusion barrier layer 613 including a nickel (Ni) layer may be additionally introduced to effectively prevent or suppress copper ions in the first end portions 220 from diffusing into the conductive layer 630 including a tin (Sn) layer.

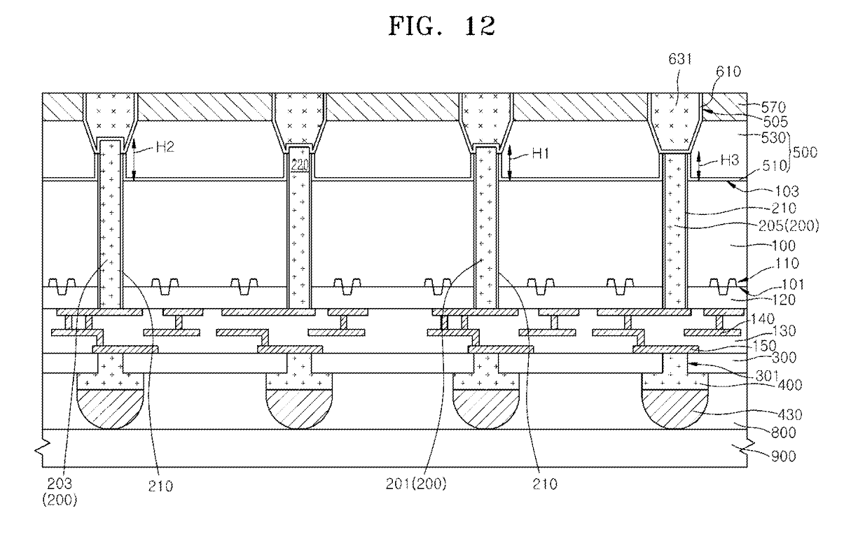

Referring to FIG. 12, the conductive layer 630 may be planarized until the lower metal layer 610 on the top surface of the template pattern 570 is exposed. The conductive layer 630 may be planarized using a chemical mechanical polishing (CMP) process. As a result, the conductive layer 630 may be separated into a plurality of first conductive bumps 631 remaining in the second openings 505. Portions of the lower metal layer 610 on the top surface of the template pattern 570 may be selectively removed using a wet etch process to expose the top surface of the template pattern 570.

In some embodiments, the lower metal layer 610 on the top surface of the template pattern 570 may be removed during the planarization of the conductive layer 630. Accordingly, the lower metal layer 610 may be separated into a plurality of patterns, and each lower metal pattern 610 may have a concave shape covering a bottom surface and a sidewall of each first conductive bump 631. The lower portions of the lower metal patterns 610 surrounding the lower portions of the first conductive bumps 631 may be covered with the first passivation layer 500. Thus, the first passivation layer 500 may prevent the lower portions of the lower metal patterns 610 from being etched. That is, the first passivation layer 500 may prevent formation of undercut regions below the first conductive bumps 631.

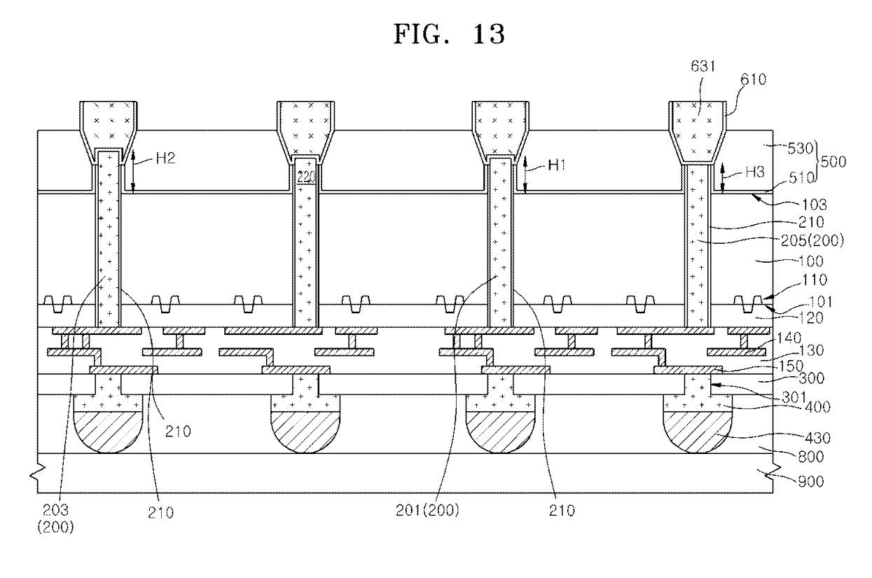

Referring to FIG. 13, the template pattern 570 may be removed to expose a top surface of the first passivation layer 500. In an embodiment in which the template pattern 570 is a photoresist layer, the template pattern 570 may be removed using an ashing process.

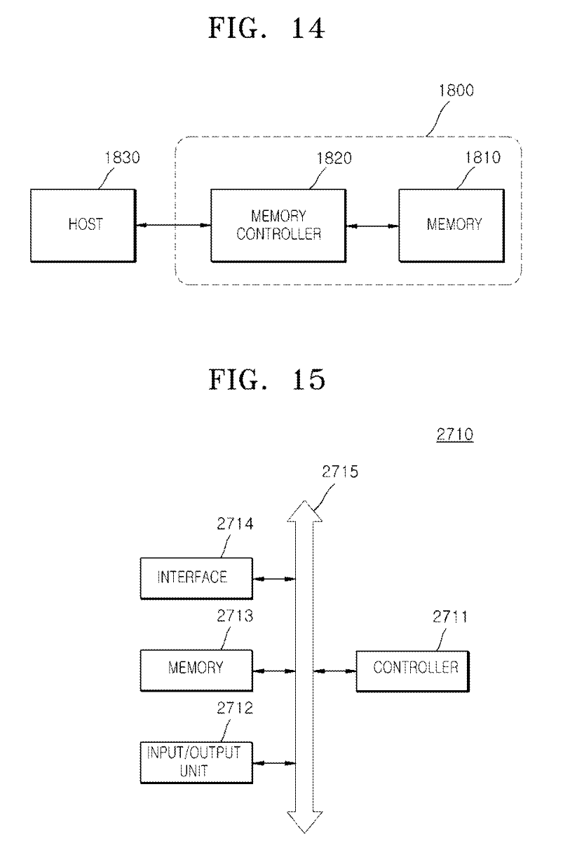

Referring to FIG. 14, a semiconductor device in accordance with an embodiments may be provided in the form of a memory card 1800. For example, the memory card 1800 may include a memory 1810 such as a nonvolatile memory device and a memory controller 1820. The memory 1810 and the memory controller 1820 may store data or read stored data.

The memory 1810 may include any one of nonvolatile memory devices to which the technology of an embodiment is applied. The memory controller 1820 may control the memory 1810 such that stored data is read out or data is stored in response to a read/write request from a host 1830.

Referring to FIG. 15, a semiconductor device in accordance with an embodiment may be applied to an electronic system 2710. The electronic system 2710 may include a controller 2711, an input/output unit 2712, and a memory 2713. The controller 2711, the input/output unit 2712 and the memory 2713 may be coupled with one another through a bus 2715 providing a path through which data moves.

For example, the controller 2711 may include at least one microprocessor, at least one digital signal processor, at least one microcontroller, or logic devices capable of performing the same functions as these components. The controller 2711 or the memory 2713 may include at least one semiconductor device according to an embodiment. The input/output unit 2712 may include at least one of a keypad, a keyboard, a display device, a touchscreen and so forth. The memory 2713 is a device for storing data. The memory 2713 may store data and/or commands to be executed by the controller 2711, and the like.

The memory 2713 may include a volatile memory device such as a DRAM and/or a nonvolatile memory device such as a flash memory. For example, a flash memory may be mounted to an information processing system such as a mobile terminal or a desk top computer. The flash memory may constitute a solid state drive (SSD). In this case, the electronic system 2710 may stably store a large amount of data in a flash memory system.

The electronic system 2710 may further include an interface 2714 configured to transmit and receive data to and from a communication network. The interface 2714 may be a wired or wireless type. For example, the interface 2714 may include an antenna or a wired or wireless transceiver.

The electronic system 2710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

In the case where the electronic system 2710 is an equipment capable of performing wireless communication, the electronic system 2710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments have been disclosed above for illustrative purposes. Those skilled in the art will appreciate that various modifications, additions and substitutions are possible, without departing from the scope and spirit of the accompanying claims.

1-12. (canceled)

13. A method of manufacturing a semiconductor device, the method comprising:
forming a passivation layer on a first surface of a substrate, the passivation layer covering a first end portion of a through electrode penetrating the substrate, the first end portion of the through electrode protruding from the first surface of the substrate;
forming a template pattern on the passivation layer to expose a portion of the passivation layer vertically overlapping with the first end portion of the through electrode;
etching the exposed portion of the passivation layer to form an opening that exposes the first end portion of the through electrode;
forming a lower metal layer contacting the first end portion of the through electrode;
forming a bump in the opening surrounded by the lower metal layer; and
removing the template pattern.

14. The method of claim 13, wherein the lower metal layer extends onto a sidewall of the opening and a top surface of the template pattern.

15. The method of claim 13, wherein forming the bump includes:
forming a conductive layer on the lower metal layer to fill the opening; and
planarizing the conductive layer to expose the lower metal layer on the template pattern,
wherein the conductive layer is formed using a plating process.

16. The method of claim 15, wherein planarizing the conductive layer is performed using a chemical mechanical polishing process.

17. The method of claim 13, wherein the template pattern is a dielectric layer or a photoresist layer.

18. A method of manufacturing a semiconductor device, the method comprising:
forming a through electrode penetrating a substrate such that a first end portion of the through electrode protrudes from a first surface of the substrate;
forming a passivation layer that covers the first surface of the substrate and a sidewall of the first end portion of the through electrode;
forming a lower metal layer over the first end portion of the through electrode; and
forming a bump having a lower portion that is penetrates the passivation layer and is coupled to the first end portion of the through electrode through the lower metal layer;
wherein the lower metal layer extends onto a sidewall of the bump and has a concave shape.

19. The method of claim 18, wherein the bump includes an upper portion protruding from a top surface of the passivation layer.

20. The method of claim 19, wherein the lower metal layer extends onto a sidewall of the upper portion of the bump.
